(19) United States
(12) Patent Application Publication
(10) Pub. No.: US 2002/0190768 A1
(43) Pub. Date: Dec. 19, 2002

(54) Extended resolution mode for a PWM module application

(76) Inventor: Stephen A. Bowling, Chandler, AZ (US)

Correspondence Address: SWIDLER BERLIN SHEREFF FRIEDMAN, LLP, 3000 K STREET, NW, BOX IP, WASHINGTON, DC, 20007, US

(21) Appl. No.: 09/870,455

(22) Filed: Jun. 1, 2001

(51) Int. Cl. H03K 3/017

(52) U.S. Cl. 327/175

(57) ABSTRACT

An extended resolution mode for a PWM generator is provided. The extended resolution mode takes advantage of the higher frequency Q clock generation scheme on processors that include the PWM generator. Specifically, a Q clock counter, which operates at four times the frequency of the oscillator fed into the rest of the PWM generator, is used to generate a two bit output. This two bit output is used as the lower order bits of an n-bit period counter of the PWM generator during a high resolution mode to generate PWM signal edges. The two upper bits of the n-bit period counter are ignored during PWM signal edge generation in high resolution mode. The high resolution mode greatly improves PWM signal control at low frequencies of operation. During a normal resolution mode, the Q clock counter is ignored during PWM signal edge generation.

### FIELD OF THE INVENTION

The present invention relates to a processor having a pulse width modulation (PWM) generator that includes an extended resolution mode to facilitate operation at low frequencies of operation.

### BACKGROUND OF THE INVENTION

Processors, including microprocessors, digital signal processors and microcontrollers, operate by running software programs that are embodied in one or more series of program instructions stored in a memory. The processors run the software by fetching the program instructions from the series of program instructions, decoding the program instructions and executing them. In addition to program instructions, data is also stored in memory that is accessible by the processor. Generally, the program instructions process data by accessing data in memory, modifying the data and storing the modified data into memory.

Processors may be programmed to perform a wide variety of functions in software. In some cases, however, dedicated hardware may be included in a processor that significantly eases the processing load needed to perform certain functions. This allows the use of lower performance processor for these functions, which lowers the cost of the processor. One type of dedicated hardware that may advantageously be included in a processor is power control hardware. Power control hardware provides the capability to control circuitry and devices that use significant amounts of power. For example, power control hardware may be used to control motors, power supplies, etc.

One common mode of operation of power control hardware is pulse width modulation (PWM). In PWM, the power level is controlled by controlling the duty cycle of a signal that has only two states—active and inactive. The signal is then connected to output transistors and a load, such as a motor, to yield the equivalent of a continuously varying voltage and current.

When PWM hardware is included in a processor, external switching devices, such as transistors, must be used in order to handle significant amounts of power. These switching devices have less than perfect switching characteristics, especially when connected to devices such as motors. Problems arise with conventional PWM hardware, which has been included in current processors, in dealing with the less than perfect switching characteristics of connected switching devices.

In some applications, it is desirable to run a processor with PWM hardware at low oscillator frequencies to conserve power or for other reasons. This can lead to additional complications because the PWM resolution is lower at lower frequencies than at higher frequencies. This is because the smallest interval in time upon which PWM signal edges may be generated becomes larger as the PWM frequency decreases. Therefore at lower frequencies, PWM signal edges are less accurately controlled leading to a situation where PWM signals generated only grossly approximate the ideal PWM signal for driving an external device. This causes power loss and sub-optimal performance of the external devices being driven.

For these reasons, there is a need for a new technique for extending the resolution used to generate PWM signals, particularly at low processor frequencies of operation.

### SUMMARY OF THE INVENTION

According to the present invention, an extended resolution mode for a PWM generator is provided. The extended resolution mode takes advantages of the higher frequency Q clock generation scheme on processors that include the PWM generator. Specifically, a Q clock counter, which operates at four times the frequency of the oscillator fed into the rest of the PWM generator, is used to generate a two bit output. This two bit output is used as the lower order bits of an n-bit period counter of the PWM generator during a high resolution mode to generate PWM signal edges. The two upper bits of the n-bit period counter are ignored during PWM signal edge generation in high resolution mode. The high resolution mode greatly improves PWM signal control at low frequencies of operation. During a normal resolution mode, the Q clock counter is ignored during PWM signal edge generation.

According to an embodiment of the invention, a pulse width modulator for a processor is provided having an extended resolution mode. The pulse width modulator includes a time base, a Q clock counter, a multiplexer and a duty cycle comparator. The time base generates a n-bit period counter that counts to a predetermined value in response to cycles of a counter clock generated based on a first oscillator signal. The Q clock counter generates a two bit output based on a second oscillator signal of the processor that has a frequency that is a multiple of the frequency of the first oscillator signal. The multiplexer is coupled to the n-bit period counter and the two bit output. Lastly, the duty cycle comparator is coupled to the multiplexer output. It determines a duty cycle based on the n-bit counter received from the multiplexer in a normal resolution mode. In a high resolution mode, it determines a duty cycle based on the n-2 lowest bits of the n-bit period counter and the two bit output received from the multiplexer.

The frequency of the second oscillator signal may be four times the frequency of the first oscillator signal according to one embodiment of the invention. Also, the time base may include clock control and prescale logic for generating the counter clock from the first oscillator signal at one of the following illustrative fractions of the first oscillator signal: 1/1, ¼/, 1/16, and 1/64.

According to another embodiment of the invention, a processor includes pulse width modulation generation circuitry and a Q clock counter. The pulse width modulation generation circuitry is operable to generate pulse width modulation signals based in part on a period counter. The Q clock counter contributes bits to a period counter within the pulse width modulation generation circuitry during a high resolution mode. The pulse width modulation generation circuitry may further include a duty cycle register and a comparator for comparing a value in the duty cycle register with the period counter and contributed Q clock counter bits.

### BRIEF DESCRIPTION OF THE FIGURES

FIG. 1 depicts a functional block diagram of an embodiment of a processor chip within which the present invention may find application.

FIG. 2 depicts a functional block diagram of a pulse width modulation (PWM) module for use in a processor, such as that shown in FIG. 1.

FIG. 3 depicts an exemplary external circuit, which may be driven by complementary PWM signals generated by the circuit shown in FIG. 2.

FIG. 4 depicts an exemplary embodiment of a time base for generating an n-bit period counter.

FIG. 5 depicts a graph illustrating the generation of an n-bit period counter and the generation of PWM signals having a particular duty cycle based on the n-bit period counter.

FIG. 6 depicts an exemplary embodiment of a PWM generator that incorporates a high resolution mode according to an embodiment of the present invention.

### DETAILED DESCRIPTION

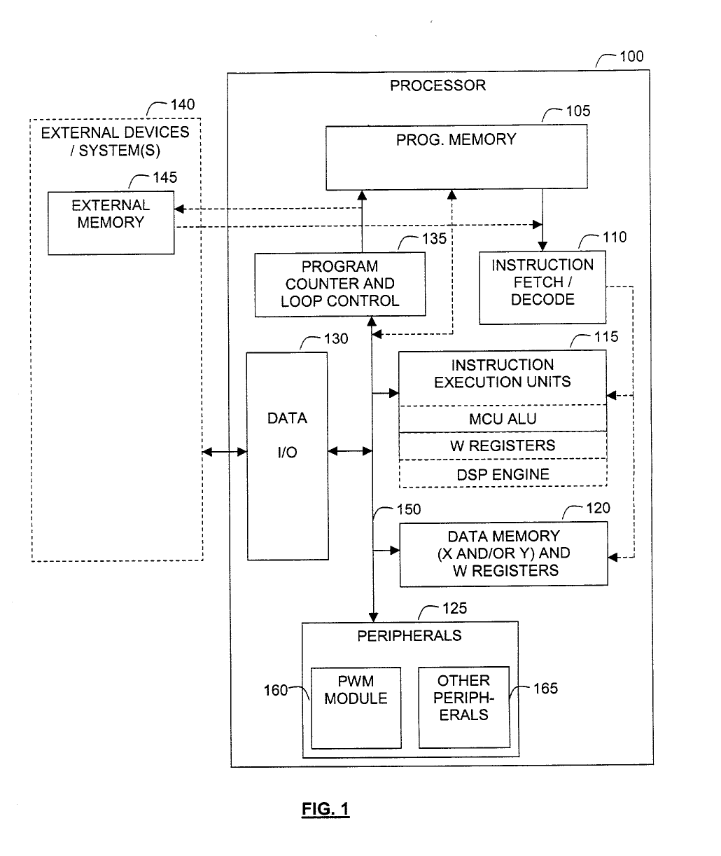

FIG. 1 depicts a functional block diagram of an embodiment of a processor chip within which the present invention may find application. Referring to FIG. 1, a processor 100 is coupled to external devices/systems 140. The processor 100 may be any type of processor including, for example, a digital signal processor (DSP), a microprocessor, a microcontroller, or combinations thereof. The external devices 140 may be any type of systems or devices including input/output devices such as keyboards, displays, speakers, microphones, memory, or other systems which may or may not include processors. Moreover, the processor 100 and the external devices 140 may together comprise a stand alone system.

The processor 100 includes a program memory 105, an instruction fetch/decode unit 110, instruction execution units 115, data memory and registers 120, peripherals 125, data I/O 130, and a program counter and loop control unit 135. The bus 150, which may include one or more common buses, communicates data between the units as shown.

The program memory 105 stores software embodied in program instructions for execution by the processor 100. The program memory 105 may comprise any type of nonvolatile memory such as a read only memory (ROM), a programmable read only memory (PROM), an electrically programmable or an electrically programmable and erasable read only memory (EPROM or EEPROM) or flash memory. In addition, the program memory 105 may be supplemented with external nonvolatile memory 145 as shown to increase the complexity of software available to the processor 100. Alternatively, the program memory may be volatile memory, which receives program instructions from, for example, an external non-volatile memory 145. When the program memory 105 is nonvolatile memory, the program memory may be programmed at the time of manufacturing the processor 100 or prior to or during implementation of the processor 100 within a system. In the latter scenario, the processor 100 may be programmed through a process called in-circuit serial programming.

The instruction fetch/decode unit 110 is coupled to the program memory 105, the instruction execution units 115, and the data memory 120. Coupled to the program memory 105 and the bus 150 is the program counter and loop control unit 135. The instruction fetch/decode unit 110 fetches the instructions from the program memory 105 specified by the address value contained in the program counter 135. The instruction fetch/decode unit 110 then decodes the fetched instructions and sends the decoded instructions to the appropriate execution unit 115. The instruction fetch/decode unit 110 may also send operand information including addresses of data to the data memory 120 and to functional elements that access the registers.

The program counter and loop control unit 135 includes a program counter register (not shown) which stores an address of the next instruction to be fetched. During normal instruction processing, the program counter register may be incremented to cause sequential instructions to be fetched. Alternatively, the program counter value may be altered by loading a new value into it via the bus 150. The new value may be derived based on decoding and executing a flow control instruction such as, for example, a branch instruction. In addition, the loop control portion of the program counter and loop control unit 135 may be used to provide repeat instruction processing and repeat loop control as further described below.

The instruction execution units 115 receive the decoded instructions from the instruction fetch/decode unit 110 and thereafter execute the decoded instructions. As part of this process, the execution units may retrieve one or two operands via the bus 150 and store the result into a register or memory location within the data memory 120. The execution units may include an arithmetic logic unit (ALU) such as those typically found in a microcontroller. The execution units may also include a digital signal processing engine, a floating point processor, an integer processor, or any other convenient execution unit.

The data memory and registers 120 are volatile memory and are used to store data used and generated by the execution units. The data memory 120 and program memory 105 are preferably separate memories for storing data and program instructions respectively. This format is a known generally as a Harvard architecture. It is noted, however, that according to the present invention, the architecture may be a Von-Neuman architecture or a modified Harvard architecture, which permits the use of some program space for data space. A dotted line is shown, for example, connecting the program memory 105 to the bus 150. This path may include logic for aligning data reads from program space such as, for example, during table reads from program space to data memory 120.

A plurality of peripherals 125 on the processor may be coupled to the bus 125. The peripherals may include pulse width modulation (PWM) module 160 and other peripherals 165, such as analog to digital converters, timers, bus interfaces and protocols such as, for example, the controller area network (CAN) protocol or the Universal Serial Bus (USB) protocol and other peripherals. The peripherals exchange data over the bus 150 with the other units. The PWM module 160 is capable of generating multiple, synchronized pulse width modulated (PWM) outputs. The PWM module 160 may be advantageously applied to a variety of power and motion control applications, such as control of Three-Phase AC Induction Motors, Switched Reluctance (SR) Motors, Brushless DC (BLDC) Motors, and Uninterruptable Power Supplies (UPSs).

The data I/O unit 130 may include transceivers and other logic for interfacing with the external devices/systems 140. The data I/O unit 130 may further include functionality to permit in circuit serial programming of the Program memory through the data I/O unit 130.

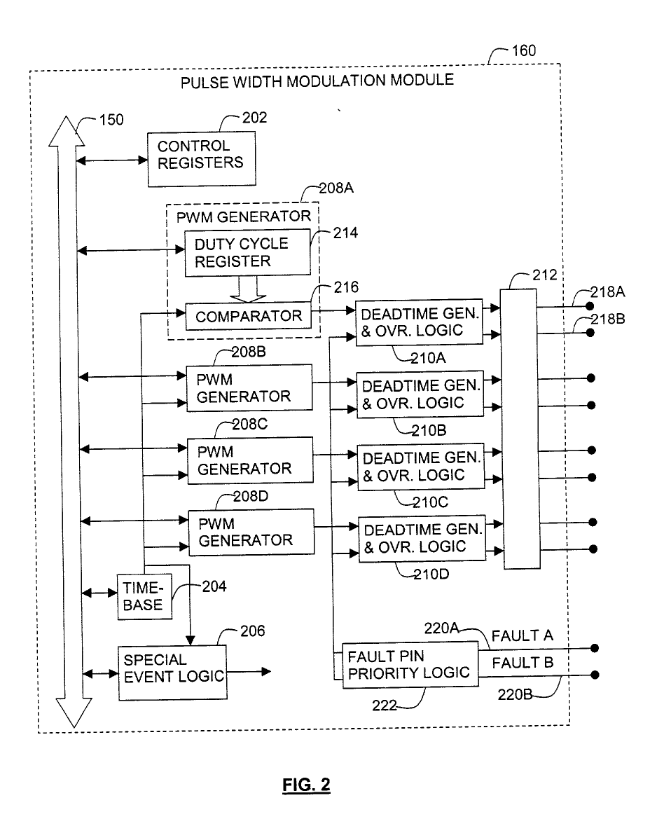

FIG. 2 depicts a functional block diagram of a pulse width modulation (PWM) module 160, for use in a processor 100, such as that shown in FIG. 1. PWM module 160 includes control registers 202, timebase 204, special event logic 206, at least one pulse width modulation generator, such as PWM generators 208A, 208B, 208C, and 208D, for each PWM generator, a deadtime generator, such as deadtime generators 210A, 210B, 210C, and 210D, and output driver circuitry 212. Bus 150 is communicates data among units of processor 100 and elements of PWM module 160. In particular, bus 150 communicates data with control registers 202, timebase 204, special event logic 206, and the at least one PWM generator, such as PWM generators 208A, 208B, 208C, and 208D.

Control registers 202 store values that are modifiable in software and provide the capability to control and configure the operation of the elements of PWM module 160. Control registers 202 may include a plurality of control registers, each control register including a plurality of bits. Each control register may be read, under software control, to determine the configuration and operational state of elements of PWM module 160. Likewise, each control register may be written, under software control, to set the configuration and control the operation of element of PWM module 160. For example, bits in control registers 202 may provide the capability to enable or disable the generation of PWM signals by PWM module 160. Bits in control register 202 may provide the capability to set the polarity and timing of signals output by PWM module 160, such as the frequency, duty cycle, and dead time of such signals. Bits in control registers 202 may provide the capability to enable, disable, and configure special event triggering, fault triggering, override operation, and other functions of PWM module 160.

Timebase 204 generates timing signals that are used by other elements of PWM module 160, such as special event logic 206 and the PWM generators 206A-D. Timebase 204 may include registers, counters, comparators, and other circuitry that operate with a timing clock signal to provide the capability to generate timing signals having programmable parameters. For example, timebase 204 may provide the capability to program parameters such as: the count direction of included counters, the resolution and prescaling of the timing clock used to generate the timebase signals, the mode of operation of timebase interrupts, postscaling of timebase signals, and the mode of operations of the timebase, such as continuous, free running, single shot, etc.

Special event logic 206 generates trigger signals that provide the capability to synchronize operations external to PWM module 160 with the operation of PWM module 160. For example, in an embodiment of processor 100 in which other peripherals 165 includes one or more analog to digital (A/D) converters, the operation of such A/D converters may be synchronized to the operation of PWM module 160 using the trigger signals generated by special event logic 206. Special event logic 206 uses signals generated by timebase 204 to generate trigger signals that are synchronized with selected points in the period of the PWM signals generated by PWM module 160.

Each PWM generator generates a PWM signal, which is input to a deadtime generator. Each PWM generator, such as PWM generator 208A, may include a duty cycle register, such as duty cycle register 214, a comparator, such as comparator 216, and associated circuitry. Duty cycle register 214 stores a value that controls the duty cycle of the PWM signals. The duty cycle of a PWM signal is the fraction of each complete PWM cycle that the signal is in the active state. Duty cycle register 214 typically includes a buffer register, which is accessible by software, and a comparison register, which stores the actual compare value used in each PWM cycle. The value in the comparison register is compared by comparator 216, to a value generated by timebase 204. The status of this comparison controls the signals output from comparator 216, which, in turn, control whether the PWM signal is in the active or inactive state.

The output from each comparator, such as comparator 216, is input to a deadtime generator, such as deadtime generator 210A. Deadtime generator 210A may pass the signal from comparator 216 without alteration, or deadtime generator 210A may alter the signal. Deadtime generator 210A may generate a set of complementary PWM signals based on the signal from comparator 216. Complementary signals are signals that are arranged so that when one signal is active, the other signal is inactive. When the active signal becomes inactive, the inactive signal becomes active, and so on. Deadtime generator 210 also inserts deadtime into the complementary signals. Deadtime is a period during which neither complementary signal is active.

The complementary PWM signals generated by each deadtime generator, such as deadtime generator 210A, is input to output driver circuitry 212, which includes circuitry of sufficient capacity to drive circuitry external to processor 100. The drive signals are supplied to external circuitry via processor pins, such as pins 218A and 218B.

Fault inputs 220A and 220B provide the capability to drive one or more of the PWM outputs to a defined state. Such a function is useful if a fault occurs in the external circuitry that is controlled by the PWM outputs of processor 100. The function of the fault inputs is performed directly in hardware, so that fault events can be managed quickly. Examples of faults that may occur include failure of an external switching device, such as a transistor, short circuit of external circuitry or devices, such as a motor, overcurrent detected in external circuitry or devices, a fault in the power supply, etc. Fault pin priority logic 222 provides the capability to prioritize the function of the fault inputs if more than one input becomes active. The signals output from fault pin priority logic 222 are input to the deadtime generators 210A-210D. The deadtime generators also include fault override logic that overrides the function of the deadtime generator in response to a fault signal from fault pin priority logic 222, if so configured.

Included in control registers 202 are registers that control the configuration and function of PWM module 160 in response to activation of one or more fault inputs. In particular, the registers provide the capability to define whether a particular pair of PWM outputs associated with a deadtime generator, such as PWM outputs 218A and 218B and deadtime generator 210A, are controlled by the fault inputs. If enabled, the override logic in the deadtime generator will respond to a fault output signal 224 from fault pin priority logic 222 and perform a defined action.

Control registers 202 store values that define the state of each PWM output in response to a fault signal input to each fault input. Each PWM output can be defined to be driven inactive or active in response to the fault signal input to each fault input. For example, PWM output 218A may be defined to be driven inactive in response to a fault signal on fault input 220A and may be defined to be driven active in response to a fault signal on fault input 220B. If a PWM output pair associated with one deadtime generator is in the complementary output mode and both PWM outputs are defined to be driven to the active state in response to a fault signal input to a fault input, both PWM outputs would be driven active, which is not desirable. In this situation, the override logic in the deadtime generator will give priority to one PWM output, drive that PWM output active, and drive the other PWM output inactive.

Fault pin priority logic 222 provides prioritization among the fault inputs. If more than one fault input has been defined to control a particular PWM output and at least two such fault inputs become active concurrently, fault pin priority logic 222 selects one of the fault inputs to be given priority. The PWM outputs are driven to the fault states defined for the fault input that has been given priority, and the other fault inputs are ignored. Fault priority logic 222 generates a fault output signal 224 that indicates the selected fault input. Fault output signal 224 in input to the deadtime generators, such as deadtime generator 210A, which drives its associated PWM outputs to the fault state defined for the selected fault input.

Each of the fault inputs has two modes of operation:

Latched Mode: When the fault input is driven active, the PWM outputs will remain in the defined fault states until the fault input is driven inactive and the fault condition is cleared in software. The PWM outputs will be enabled for normal, non-fault operation once the fault condition is cleared in software.

Cycle-by-Cycle Mode: When the fault input is driven active, the PWM outputs will remain in the defined fault states until the fault input is driven inactive. When the fault input is driven inactive, the PWM outputs will return to normal, no-fault operation at the beginning of the next PWM period.

The mode of operation of each fault input is defined in registers included in control registers 202.

Each fault input may also be controlled directly by software. Processor 100 can be configured so that software can directly drive the active or inactive levels of each fault input.

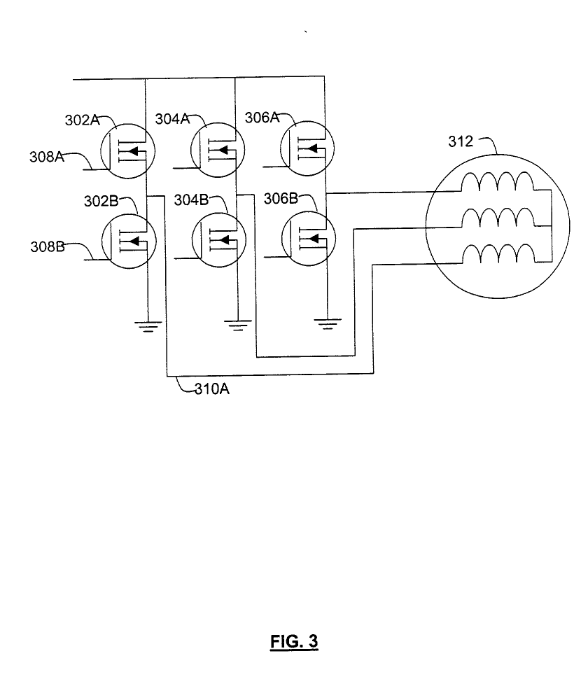

An example of an external circuit that may be driven by complementary PWM signals is shown in FIG. 3. In this example, three transistor pairs, a first pair including transistors 302A and 302B, a second pair including transistors 304A and 304B, and a third pair including transistors 306A and 306B, are connected to complementary PWM outputs of processor 100, either directly or via appropriate additional circuitry. For example, the signal on pin 218A, shown in FIG. 2, may be connected to input 308A of transistor 302A and the complementary signal on pin 218B, also shown in FIG. 2, may be connected to input 308B of transistor 302B. One of skill in the art would recognize that pins 218A and 218B would typically be connected to inputs 308A and 308B, respectively, via appropriate, and well-known, circuitry. Other complementary PWM outputs from processor 100 may similarly be connected to inputs to other transistor pairs.

The output from each transistor pair is formed at a connection between the transistors in the pair. In the example shown, which uses transistors that are MOSFETs, the output of each transistor pair is formed at the connection between the source of the upper transistor and the drain of the lower transistor. For example, output 310A is formed at the connection of the source of transistor 302A and the drain of transistor 302B. The outputs of the transistor pairs are connected to windings of motor 312 and supply the power that drives motor 312.

In the example of FIG. 3, MOSFET transistors and a three-phase AC induction motor are illustrated. One of skill in the art would, of course, recognize that other types of transistors and other types of motors could be used as well as those illustrated. For example, transistors, such as bipolar transistors, insulated-gate bipolar transistors, and other well-known types of transistors, or motors, such as switched reluctance (SR) motors, or brushless DC (BLDC) motors could be used instead of those illustrated, with well-known modifications to the circuitry. Likewise, as is well-known, the PWM signals could be used to control other applications, such as switching power supplies, etc.

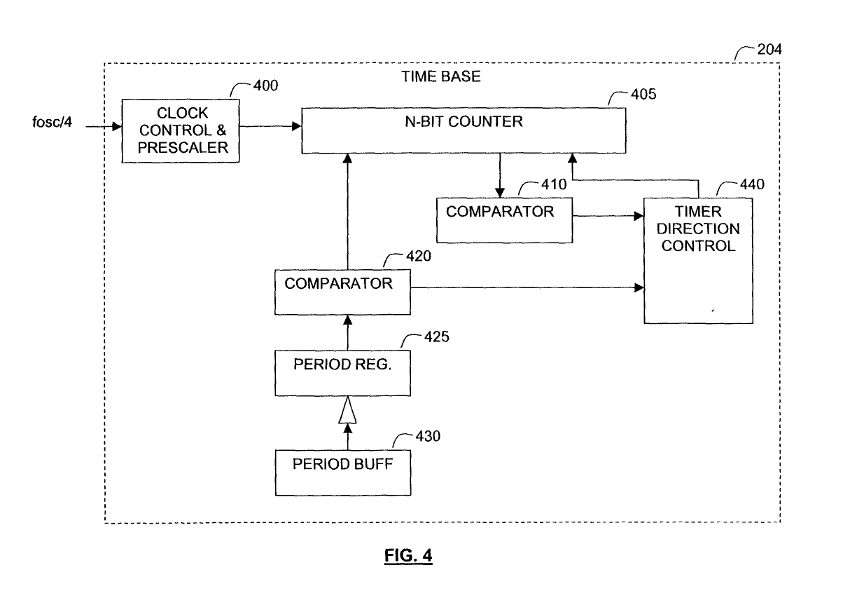

FIG. 4 depicts an exemplary embodiment of a time base 204 for generating an n-bit period counter 405 in response to cycles of an oscillator frequency. The oscillator frequency according to one embodiment of the invention is an oscillator frequency arriving at the processor divided by four (fosc/4).

Referring to FIG. 4, the signal fosc/4 is coupled to Clock Control & Prescaler logic 400. This logic generates a counter clock signal that is a selected integer fraction the signal fosc/4. The fraction may be for example 1:1, 1:4, 1:16, 1:64 or any other convenient value. The counter clock signal is output to an n-bit period counter 405.

The n-bit period counter 405 receives control signals from the timer direction control unit 440 that may determine, for example, whether the counter is to count up or down or be reset. The n-bit period counter 405 receives the counter clock signal and counts in the commanded direction based on passing cycles of the counter clock signal.

The n-bit period counter outputs its value to comparators 410 and 420. The comparator 410 compares the value of the n-bit period counter with zero and generates control signals output to the timer direction control unit 440 that reflect when the n-bit period counter reaches zero.

The comparator 420 is coupled to a period register 425 which stores a period limit value that corresponds to a desired period for a PWM signal given a desired frequency of the counter clock signal. The comparator 420 compares the n-bit period counter value with the period limit value and generates control signals output to the timer direction control unit 440 that reflect when the n-bit period counter reaches the period limit value.

The timer direction control unit 440 receives the control signals from the comparators 410 and 420 and generates control signals for the n-bit period counter 405 based on a mode of operation. There may be, for example, four modes of operation.

In a free running mode, the n-bit period counter 405 increments until the timer comparator 420 indicates that the n-bit period counter 405 equals the period limit value. In response to this event, the time direction control unit 440 resets the counter 405 to a zero value. Subsequently, the counter 405 increments again until the period limit value is reached.

Other modes include single-shot mode, continuous up/down count mode and continuous up/down count mode with interrupts for double updates. In the single shot mode, an enable signal gates the counter so that counter will go through only once cycle of incrementing from zero to the period limit value. In the other modes, both comparators 410 and 420 are used by the timer direction control unit 440 to cause the counter to increment from zero to the period limit value and to decrement from the period limit value to zero continuously.

A period buffer 430 may be implemented to temporarily store a new period limit value that is loaded into the period register 425 in response to a control signal from the timer direction control unit 440 which indicates that the old period limit value has been reached. There may be other triggering events as well that cause the buffer signal to be loaded into the period register 425.

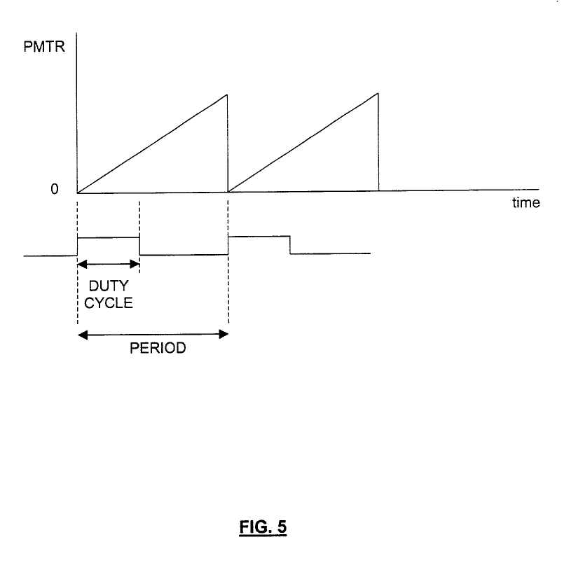

FIG. 5 illustrates a graph of the value in the n-bit period counter over time in the free running mode.

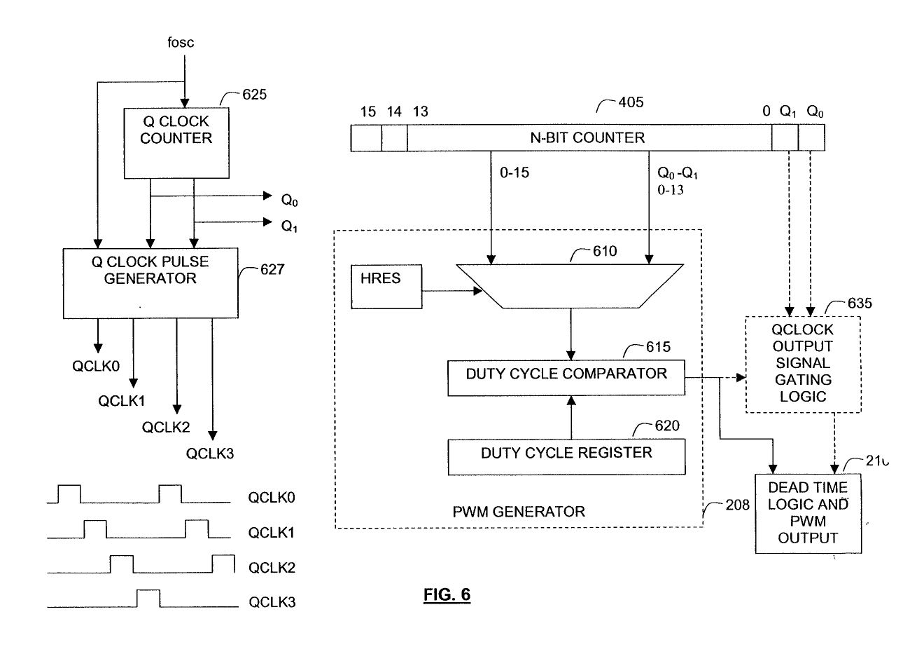

FIG. 6 depicts an exemplary embodiment of a PWM generator 208 that incorporates a high resolution mode according to an embodiment of the present invention.

Referring to FIG. 6, the PWM generator 208 includes a multiplexer 610, a duty cycle comparator 615 and a duty cycle register 620. The multiplexer 610 receives inputs based on the n-bit period counter 405 and a Q clock counter 625 on the processor. In the illustrated embodiment, the n-bit period counter 405 is a 16 bit value.

At one input, the multiplexer 610 receives all 16 bits from the counter 405. At the other input, the multiplexer 610 receives the lower 14 bits from the counter 405 and receives Q₁ and Q₀ bits from the Q clock counter 625. The multiplexer 610 is coupled to a HRES control bit 630. When the HRES control bit is set to a normal resolution mode of operation, the multiplexer 610 selects all 16 bits of the counter 405 to output to the duty cycle comparator 615. When the HRES control bit is set to an extended resolution mode of operation, the multiplexer 610 selects the lower 14 bits from the counter 405 and receives Q₁ and Q₀ bits from the Q clock counter 625.

The Q clock counter 625 receives an oscillator signal of the processor (fosc) that is not divided by 4. Accordingly, the fosc signal is four times higher than the signal entering the Clock Control & Prescaler 400. The Q clock counter generates a two bit counter output, with the two bits being designated Q₁ and Q₀. The Q clock counter is used as an input to Q clock generation on the processor. The bits Q₁ and Q₀ are exploited according to the present invention to extend the resolution of the n-bit period counter 405, thus improving accuracy in PWM signal generation, particularly at low frequencies.

The values Q₁ and Q₀ are fed into Q clock pulse generation logic 627 along with the oscillator signal fosc. The Q clock pulse generation logic 627 uses the values Q₁ and Q₀ to gate the clock signal fosc to produce the four Q clocks QCLK0-QCLK4, the phases of which are illustrated. The Q clocks are used to control instruction fetch and execute cycles on the processor.

The following sequence of events may comprise, for example, the fetch instruction cycle:

| | |
|---|---|
| Q1: | Fetch Instruction |
| Q2: | Fetch Instruction |
| Q3: | Fetch Instruction |
| Q4: | Latch Instruction into prefetch register, Increment PC |

The following sequence of events may comprise, for example, the execute instruction cycle for a single operand instruction:

| | |
|---|---|
| Q1: | latch instruction into instruction reg., decode and |
| | determine operand address data |
| Q2: | fetch operand |
| Q3: | execute function specified by instruction and |
| | calculate destination address for data |
| Q4: | write result to destination |

Referring again to FIG. 6, a duty cycle register 620 stores a value that controls the duty cycle of the PWM signals. The duty cycle of a PWM signal is the fraction of each complete PWM cycle that the signal is in the active state. The duty cycle register 620 typically has associated with it a buffer register (not shown), which is accessible by software and updates the duty cycle register 620 upon the occurrence of predetermined events.

The value in the duty cycle register 620 is compared to the value output by the multiplexer 610. The status of this comparison controls the signals output from comparator 615, which, in turn, control whether the PWM signal is in the active or inactive state. More specifically, the output of the comparator 615 controls the placement of the edges of the PWM signal in time relative to the counter value output by the multiplexer 610 as shown in FIG. 5. In a high resolution mode, 4 times more counter increments occur per unit time. Accordingly, the placement of PWM signal edges may be more accurately controlled, particularly at low fosc frequencies.

The output from the comparator 615 is input to an associated deadtime generator, such as deadtime generator 210A, as shown in FIG. 2. From there, complementary PWM signals are generated and applied to drive circuitry external to the processor 100 as shown and described with reference to FIG. 2.

As an alternative embodiment, Q clock output signal gating logic 635 maybe implemented. According to this embodiment, during the high resolution mode, the multiplexer 610 delivers bits 0-13 of the counter 405 to the comparator 615. The output of the comparator 615 is then provided to the Q clock output signal gating logic 635 as above. The gating logic 635 then gates the comparator output signal with one of the Q clock signals QCLK0-QCLK3 identified by the two bit value Q₁ and Q₀. This increases the resolution by opening up a fine adjustment window in which the duty cycle edge may be placed at one of the four Q clock edges to provide additional accuracy.

While specific embodiments of the present invention have been illustrated and described, it will be understood by those having ordinary skill in the art that changes may be made to those embodiments without departing from the spirit and scope of the invention.

What is claimed is:

1. A pulse width modulator for a processor having a selectable extended resolution mode, comprising:
a time base coupled to a first oscillator signal of the processor, the time base generating a n-bit period counter that counts to a predetermined value in response to cycles of a counter clock generated based on a first oscillator signal;
a Q clock counter coupled to a second oscillator signal of the processor, the Q clock counter generating a two bit output and the second oscillator signal being a multiple of the frequency of the first oscillator signal;
a multiplexer coupled to the n-bit period counter and the two bit output;
a duty cycle comparator coupled to the multiplexer output, the duty cycle comparator determining a duty cycle based on the n-bit counter received from the multiplexer in a normal resolution mode and determining a duty cycle based on the n-2 lowest bits of the n-bit period counter and the two bit output received from the multiplexer in the high resolution mode.

2. The pulse width modulator according to claim 1, wherein the multiple of the frequency is four.

3. The pulse width modulator according to claim 1, wherein the time base includes clock control and prescaler logic for generating the counter clock from the first oscillator signal.

4. The pulse width modulator according to claim 1, wherein the clock control and prescaler logic generates the counter clock as one of the following fractions of the first oscillator signal: 1/1, ¼, 1/16, and 1/64.

5. A processor comprising:
pulse width modulation generation circuitry operable to generate pulse width modulation signals; and
a Q clock counter;
wherein the Q clock counter contributes bits to a period counter within the pulse width modulation generation circuitry during a high resolution mode.

6. The processor according to claim 5, further comprising:
wherein the pulse width modulation generation circuitry further comprises:
a duty cycle register; and
a comparator for comparing a value in the duty cycle register with the period counter having contributed Q clock counter bits.

7. The processor according to claim 6, wherein at least some of the pulse width modulation signals generated are generated based on an output from the comparator.
